(19) United States
(12) Patent Application Publication
(10) Pub. No.: US 2018/0047807 A1
(43) Pub. Date: Feb. 15, 2018

(54) DEEP TRENCH CAPACITORS WITH A DIFFUSION PAD

(71) Applicant: GLOBALFOUNDRIES Inc., Grand Cayman (KY)

(72) Inventors: Herbert L. Ho, New Windsor, NY (US); Byeong Y. Kim, Lagrangeville, NY (US); Joyce C. Liu, Carmel, NY (US)

(21) Appl. No.: 15/233,229

(22) Filed: Aug. 10, 2016

(51) Int. Cl. H01L 49/02; H01L 21/768; H01L 21/285; H01L 27/06; H01L 23/535; H01L 21/02

(52) U.S. Cl. CPC H01L 28/60; H01L 23/535; H01L 21/02271; H01L 21/28506; H01L 27/0629; H01L 21/76895

(57) ABSTRACT

Device structures for a deep trench capacitor and methods of fabricating device structures for a deep trench capacitor. A dielectric layer is formed on a substrate and an opening is formed that extends from a top surface of the dielectric layer through the dielectric layer. A deep trench is formed in the substrate and is aligned with the opening in the dielectric layer. A plate of a deep trench capacitor is formed that is located at least partially inside the deep trench and at least partially inside the opening in the dielectric layer. A diffusion pad is formed that arranged at the top surface of the dielectric layer relative to the opening such that the diffusion pad is coupled with the plate of the deep trench capacitor.

### BACKGROUND

The present invention relates to semiconductor device fabrication and integrated circuits and, more specifically, to device structures for deep trench capacitors, as well as methods of fabricating device structures for a deep trench capacitor.

Deep trench capacitors may be used in a variety of integrated circuits, such as a charge storage device of a memory cell, a passive component of a radio frequency circuit, or a decoupling capacitor that promotes a stable voltage supply in an integrated circuit. A deep trench capacitor may include a deep trench etched into a substrate and an electrode, often deemed a buried plate, having the form of a heavily-doped region of the substrate surrounding the deep trench. A deep trench capacitor may further include another electrode, often deemed a top plate, that includes a conductor formed inside the deep trench. A thin layer of an insulating material, often deemed a node dielectric, lines the deep trench and isolates the buried and top plates from each other.

Improved device structures and fabrication methods are needed for a deep trench capacitor.

### SUMMARY

According to an embodiment, a structure includes a dielectric layer on a substrate. The dielectric layer includes a top surface and an opening that extends from the top surface through the dielectric layer. The structure further includes a deep trench capacitor having a deep trench in the substrate and a plate. The deep trench is aligned with the opening in the dielectric layer. The plate is located at least partially inside the deep trench and at least partially inside the opening in the dielectric layer. A diffusion pad is arranged at the top surface of the dielectric layer relative to the opening such that the diffusion pad is coupled with the plate of the deep trench capacitor.

According to another embodiment, a method includes forming a dielectric layer on a substrate and forming an opening that extends from a top surface of the dielectric layer through the dielectric layer. A deep trench is formed in the substrate and is aligned with the opening in the dielectric layer. A plate of a deep trench capacitor is formed that is located at least partially inside the deep trench and at least partially inside the opening in the dielectric layer. A diffusion pad is formed that arranged at the top surface of the dielectric layer relative to the opening such that the diffusion pad is coupled with the plate of the deep trench capacitor.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-5 are cross-sectional views of a substrate at successive fabrication stages of a processing method to form a deep trench capacitor in accordance with embodiments of the invention.

FIG. 5A is a cross-sectional view of a different portion of a substrate at the fabrication stage of FIG. 5.

### DETAILED DESCRIPTION

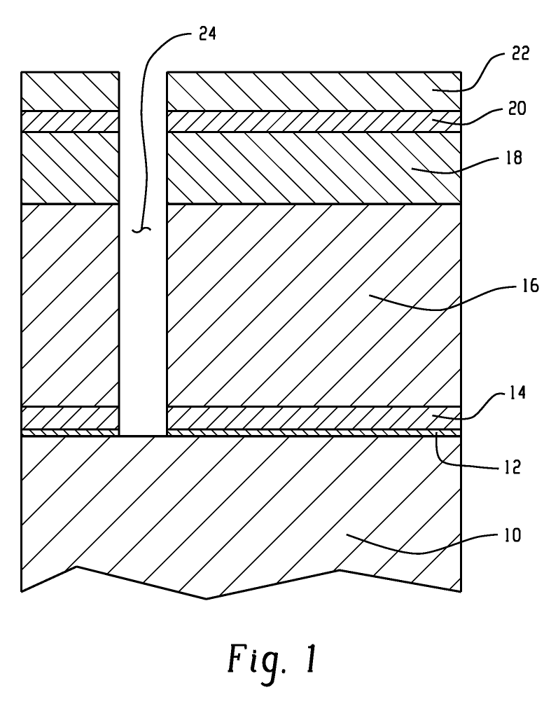

With reference to FIG. 1 and in accordance with an embodiment of the invention, a pad layer 12, a pad layer 14, and a hardmask layer 16 are located on a top surface of substrate 10 with the pad layer 12 in direct contact with the top surface of the substrate 10. The pad layer 14 has a top surface 15 that is separated from the top surface of the substrate 10 by the full thickness of the layers 12, 14. The substrate 10 may be, for example, a bulk semiconductor wafer suitable for forming an integrated circuit, and may include device structures, such as field-effect transistors, fabricated by front-end-of-line (FEOL) processing. The materials forming the pad layers 12, 14 and the hardmask layer 16 may be selected to etch selectively to the semiconductor material constituting the substrate 10 and to be readily removed at a subsequent fabrication stage. The pad layers 12, 14 are not electrically active and are used, as described hereinbelow, for isolation and patterning purposes.

The pad layers 12, 14 operate as protection layers for the top surface of the substrate 10 during, for example, etching processes. Pad layer 12 may be composed of a dielectric material, such as silicon dioxide (SiO₂) grown by oxidizing the top surface of substrate 10 or deposited by chemical vapor deposition (CVD). Pad layer 14, which may be thicker than pad layer 12, may be composed of a dielectric material, such as silicon nitride (Si₃N₄) deposited by CVD. The hardmask layer 16, which is separated from the top surface of the substrate 10 by the pad layers 12, 14, may be composed of a dielectric material, such as silicon dioxide (SiO₂), deposited by CVD. The hardmask layer 16 may be appreciably thicker than either of the pad layers 12, 14.

The hardmask layer 16 may be sequentially coated with an organic dielectric layer (ODL) 18, an anti-reflective coating (ARC) 20, and a photoresist layer 22. The ODL 18 can include an organic polymer formed using spin-on techniques. The ARC 20, which is applied before the photoresist layer 22, may be an organic material applied using spin-on techniques or an inorganic material that is deposited. The photoresist layer 22 may be applied by a spin coating process, pre-baked, exposed to light projected through a photomask, baked after exposure, and developed with a chemical developer to form a pattern that includes an opening 24 at the intended location of a subsequently-formed deep trench. The opening 24 in the photoresist layer 22 may be extended through the ARC 20, the ODL 18, the hardmask layer 16, and the pad layers 12, 14 with one or more reactive-ion etching (ME) processes each having a given etch chemistry. The opening 24 may also extend to shallow depth into the substrate 10.

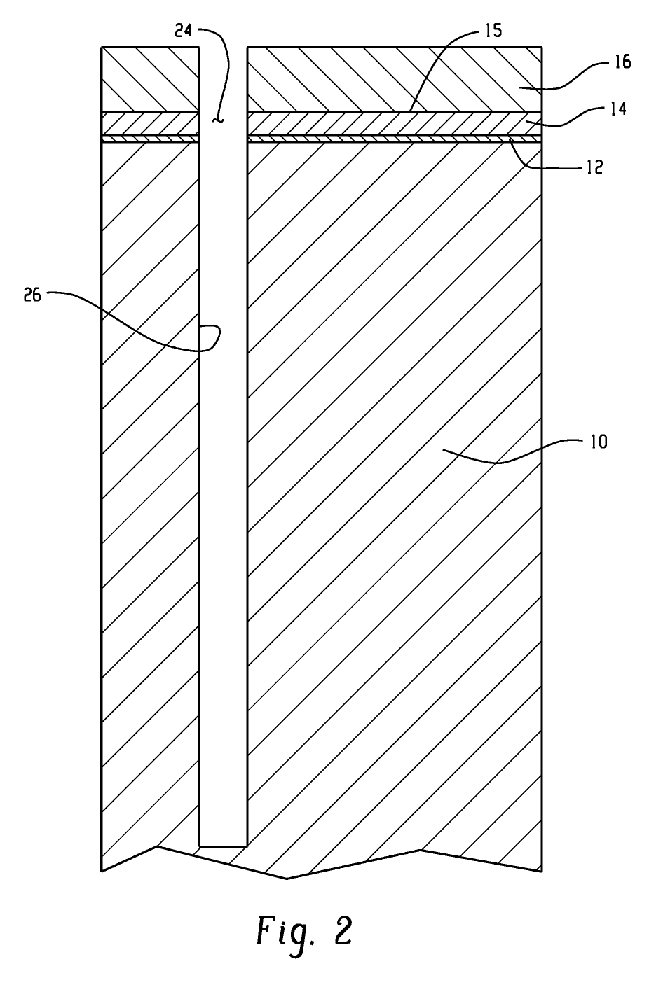

With reference to FIG. 2 in which like reference numerals refer to like features in FIG. 1 and in a subsequent fabrication stage of the processing method, the ODL 18, ARC 20, and photoresist layer 22 may be removed after the opening 24 is formed in the layers 12, 14, 16. A deep trench 26, which is aligned vertically with the opening 24, is formed in the substrate 10 by extending the opening 24 into or further into the substrate 10 with an etching process. Additional deep trenches like deep trench 26 may be formed at other locations distributed horizontally across the surface of substrate 10. The deep trench 26 may penetrate vertically from the top surface of the substrate 10 to a depth, D1, into the substrate 10 greater than one (1) micron into the substrate 10, in contrast to a shallow trench having a depth of less than 1 micron.

The etching process, which may be a ME process, removes the substrate 10 at the location of the opening 24 while the surrounding substrate 10 is protected against etching by the layers 12, 14, 16. The etching process may be conducted in a single etching step or multiple etching steps with different etch chemistries. For example, an etch chemistry capable of removing the constituent semiconductor material of the substrate 10 selective to the material constituting the materials of the layer 12, 14, 16 may be utilized to form the deep trench 26. As used herein, the term “selective” in reference to a material removal process (e.g., etching) denotes that the material removal rate (e.g., etch rate) for the targeted material is higher than the removal rate for at least another material exposed to the material removal process.

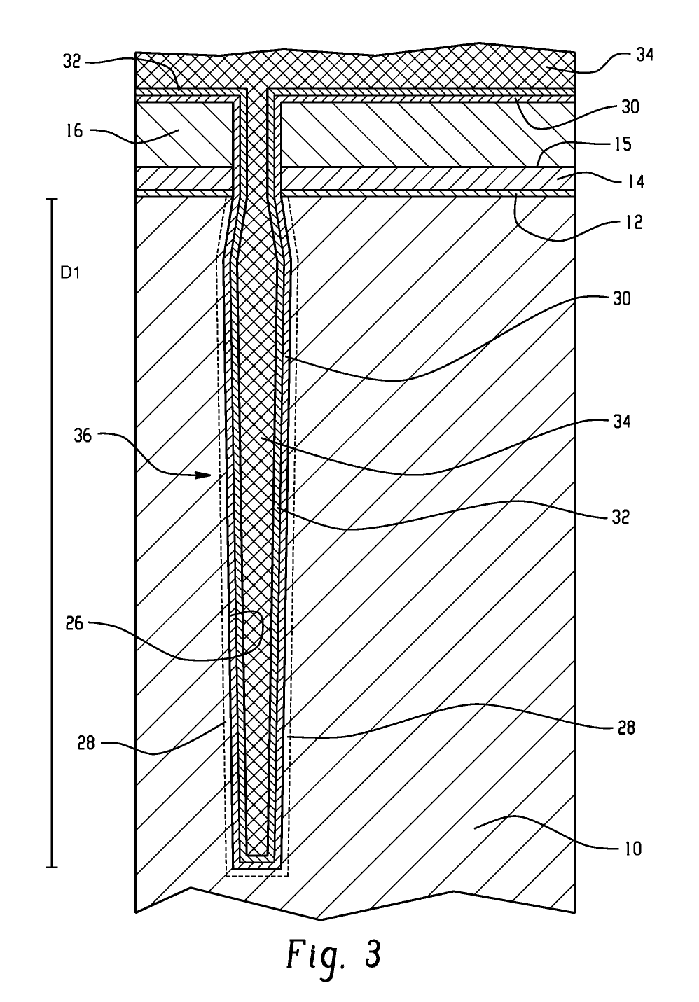

With reference to FIG. 3 in which like reference numerals refer to like features in FIG. 2 and in a subsequent fabrication stage of the processing method, a wet chemical etch may be performed to clean by-products of the etching process from the interior of the deep trench 26. The wet chemical etch may widen the sidewalls of the deep trench 26 and, in particular, may impart a bottle shape to the deep trench 26. In particular, the widest portion of the deep trench 26 is not located at the top surface of the substrate 10 but is instead positioned at a location slightly beneath the top surface of the substrate 10. The width of the deep trench 26 progressively increases, in conjunction with the bottle shape, with increasing depth from the top surface until the widest sidewall separation is achieved, and then progressively decreases with increasing depth toward the bottom of the deep trench 26.

After the deep trench 26 is formed and wet etched, a heavily-doped region 28 may be formed in the semiconductor material of the substrate 10 surrounding the deep trench 26. The heavily-doped region 28 constitutes a bottom or buried plate of a deep trench capacitor 36, and may be formed in the substrate 10 by introducing a suitable p-type or n-type dopant using, for example, ion implantation. To that end, the heavily-doped region 28 may be formed using an ion implantation tool by implanting energetic ions with one or more selected implantation conditions (e.g., ion species, dose, kinetic energy, angle of incidence) and potentially with reliance upon sidewall scattering of the ions. In an embodiment, the heavily-doped region 28 may be doped with an n-type dopant from Group V of the Periodic Table (e.g., phosphorus (P), arsenic (As), or antimony (Sb)). When the dopant is electrically activated by an anneal, the heavily-doped region 28 may exhibit a reduced electrical resistance in comparison with the surrounding undoped substrate 10.

A dielectric layer 30 is formed on the bottom surface and sidewalls of the deep trench 26. The dielectric layer 30 may be comprised of a material that is an electrical insulator, such as silicon dioxide (SiO₂), silicon oxynitride (SiON), silicon nitride (Si₃N₄), and/or hafnium oxide deposited by CVD.

A conductor layer 32 is formed on the dielectric layer 30 covering the bottom and sidewall surfaces of the deep trench 26. The conductor layer 32 may be comprised of a material characterized by a high electrical conductivity, such as a metal like titanium (Ti), titanium nitride (TiN), tantalum (Ta), tantalum nitride (TaN), or a multilayer combination of these metals deposited by physical vapor deposition (PVD) or low-pressure chemical vapor deposition (LPCVD). The remaining space inside the deep trench 26 may be filled with a conductor layer 34 comprised of a low resistivity material, such as doped polysilicon deposited by CVD. In an embodiment, the conductor layer 34 may be in situ doped during deposition with a dopant from Group V of the Periodic Table (e.g., phosphorus (P), arsenic (As), or antimony (Sb)) in a concentration that is effective to impart a designated n-type conductivity. In an embodiment, the conductor layer 34 may be formed with a single deposition process and does not require multiple deposition processes that involve recessing and planarization. The conductor layers 32, 34 may form a top or inner plate of the deep trench capacitor 36. The dielectric layer 30 functions as a node dielectric of the deep trench capacitor 36 by electrically isolating the heavily-doped region 28 from the conductor layers 32, 34. The conductor layers 32, 34 and the dielectric layer 30 adopt the shape of the deep trench 26. As a result, the conductor layers 32, 34 providing the inner plate of the deep trench capacitor 36 nominally penetrates to the depth, D1, of the deep trench 32.

Respective portions of the conductor layers 32, 34 and dielectric layer 30 are located on the vertical surfaces of the pad layers 12, 14 that border the opening 24. Consequently, the conductor layers 32, 34 forming the inner plate and the dielectric layer 30 are partially located outside of the deep trench 26 and extend vertically through the pad layers 12, 14 to the top surface 15 of the pad layer 14. In other words, the conductor layers 32, 34 are partially located in the opening 24 in the pad layers 12, 14, in addition to being partially located in the deep trench 26.

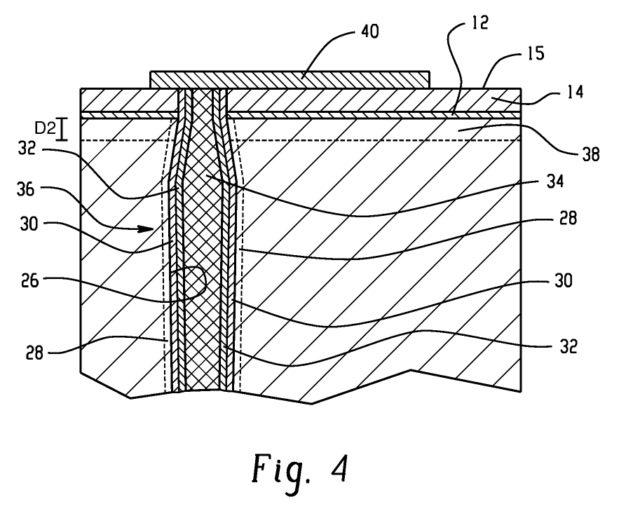

With reference to FIG. 4 in which like reference numerals refer to like features in FIG. 3 with the deep trench 26 truncated for purposes of illustration and in a subsequent fabrication stage of the processing method, the hardmask layer 16, the dielectric layer 30, and the conductor layers 32, 34 are removed from the field area on the top surface 15 of the pad layer 14 by planarization, such as with one or more chemical mechanical polishing (CMP) processes. Material removal during each CMP process combines abrasion and an etching effect that polishes the targeted material. Each CMP process may be conducted with a commercial tool using standard polishing pads and slurries selected to polish the targeted material.

A doped band 38 may be formed in the substrate 10 beneath the pad layers 12, 14. The doped band 38 may be formed by implanting energetic ions with one or more selected implantation conditions (e.g., ion species, dose, kinetic energy, angle of incidence). In an embodiment, the doped band 38 may have the same conductivity type as the heavily-doped region 28. In an embodiment, the doped band 38 may be doped by implantation with a dopant from Group V of the Periodic Table (e.g., phosphorus (P), arsenic (As), or antimony (Sb)) in a concentration and with a depth profile that is effective to impart a designated n-type conductivity. When the dopant is electrically activated by an anneal, the doped band 38 may exhibit a reduced electrical resistance in comparison with the underlying semiconductor material of substrate 10. The doped band 38 is coupled with the heavily-doped region 28 of the deep trench capacitor 36, and may be used to couple the buried plates of other deep trench capacitors with the heavily-doped region 28 of the deep trench capacitor 36. The doped band 38 replaces an n-well in the process flow of record. The band 38 of doped semiconductor material penetrates to a depth, D2, in the substrate that is shallower than the depth, D1, of the deep trench 32.

A diffusion pad 40 is arranged on the top surface 15 of the pad layer 14 so as to be placed in contact with the conductor layers 32, 34 that provide the inner plate of the deep trench capacitor 36. The diffusion pad 40 may be formed by patterning a conductive layer deposited on the top surface 15 of the pad layer 14 with photolithography and etching processes. In an embodiment, the diffusion pad 40 may be comprised of a conductive material capable of forming a silicide, such as polysilicon deposited by LPCVD or by another deposition technique. To reduce its electrical resistivity, the diffusion pad 40 may be doped either in situ during deposition or subsequent to deposition by ion implantation. In an embodiment, the diffusion pad 40 may have the same conductivity type as the conductor layer 34. In an embodiment, the diffusion pad 40 may be doped with a dopant from Group V of the Periodic Table (e.g., phosphorus (P), arsenic (As), or antimony (Sb)) in a concentration that is effective to impart a designated n-type conductivity. The diffusion pad 40 represents an “active” silicon region that is associated with the deep trench capacitor 36, and that is formed by deposition and masked patterning. The diffusion pad 40 is larger in area, from a perspective normal to its top surface and the top surface 15 of pad layer 14, than the area of the conductor layers 32, 34 inside the deep trench 26 at the top surface 15 of pad layer 14.

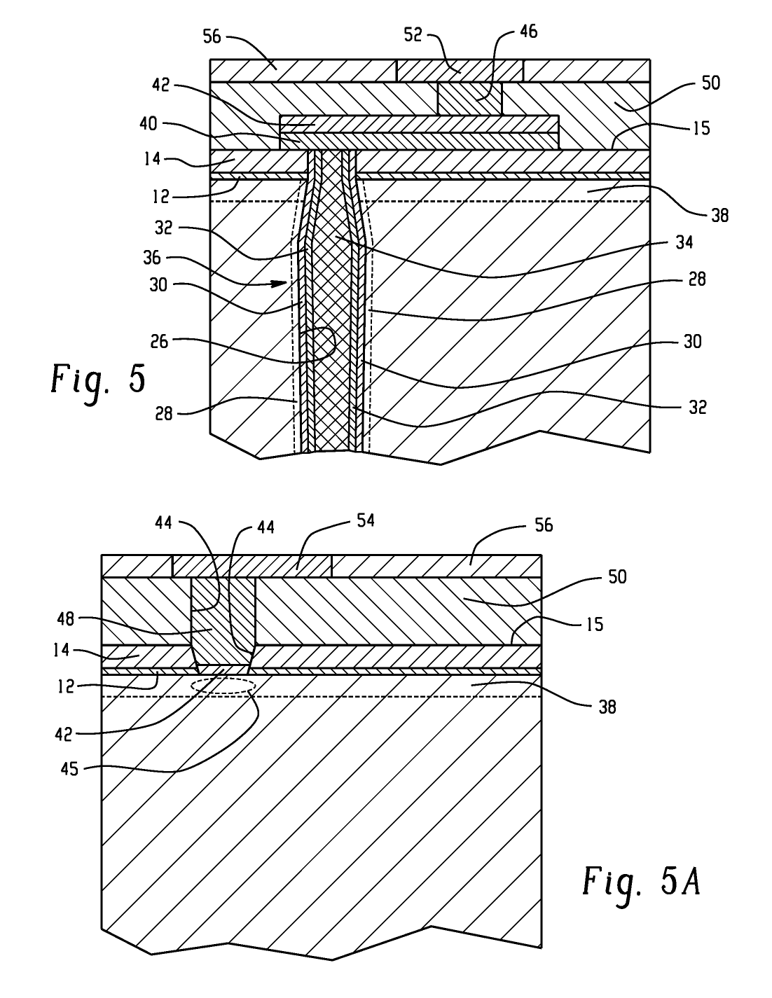

With reference to FIGS. 5, 5A in which like reference numerals refer to like features in FIG. 4 and in a subsequent fabrication stage of the processing method, a silicide layer 42 is formed on the diffusion pad 40. The silicide layer 42 may be formed by a silicidation process that involves one or more annealing steps to form a silicide phase by reacting a deposited layer of silicide-forming metal and the semiconductor material of the diffusion pad 40 in contact with the silicide-forming metal. Candidate materials for the silicide-forming metal include, but are not limited to, metals such as titanium (Ti), cobalt (Co), or nickel (Ni). The diffusion pad 40 and its silicide layer 42 may be used to interconnect the deep trench capacitor 36 with multiple other similar deep trench capacitors.

Because the diffusion pad 40 is formed on the top surface 15 of the pad layer 14 and the top plate provided by conductor layers 32, 34 penetrates through the pad layers 12, 14, the top plate of the deep trench capacitor 36 is electrically isolated from the heavily-doped region 28 defining the bottom plate by the pad layers 12, 14. As a consequence, the electrical isolation of the top plate and the bottom plate of the deep trench capacitor 36 against electrical conduction does not require another isolation process (i.e., shallow trench isolation). In other words, the substrate 10 is free of trench isolation regions adjacent to the deep trench capacitor 36.

Contacts 46, 48 of a local interconnect level are formed in respective contact openings that extend through a dielectric layer 50 that is applied on the pad layers 12, 14. Contact 46 extends vertically through a contact hole in the dielectric layer 50 to the diffusion pad 40. As shown in FIG. 5A, the contact 48 is located in a contact hole 44 that is formed in the pad layers 12, 14 at a location adjacent to the deep trench capacitor 36. The contact 48 is coupled with a source/drain region 45 of an access field-effect transistor that is associated with the deep trench capacitor 36. The doped band 38 extends horizontally to the location of the contact hole 44, and the source/drain region 45 intersects the doped band 38 at that location. The doped band 38 connects the source/drain region 45 with the buried plate of the deep trench capacitor 36.

A wiring level includes wiring 52, 54 that is formed in trenches defined in a dielectric layer 56. The wiring level may represent a first wiring level that is closest to the substrate 10. Wiring 52 is coupled by the contact 46 with the diffusion pad 40, and wiring 54 is coupled by the contact 48 with the doped band 38 and the source/drain region 45.

The contacts 46, 48, wiring 52, 54, and dielectric layers 50, 56 may be formed during middle-of-line (MOL) processing and/or back-end-of-line (BEOL) processing. The dielectric layers 50, 56 may be comprised of an electrically-insulating material, such as silicon dioxide deposited by CVD. A liner (not shown) comprised of titanium (Ti), titanium nitride (TiN), tantalum (Ta), tantalum nitride (TaN), or a layered combination of these materials (e.g., a bilayer of TaN/Ta) may be applied to the contact holes and trenches before filling. Contacts 46, 48 may be comprised of an electrically-conductive material, such as tungsten (W), deposited by CVD in the contact openings. The wiring 52, 54 may be comprised of a low-resistivity metal, such as copper (Cu), formed using a deposition process, such as electroplating or electroless deposition.

In an alternative embodiment, the substrate 10 may be an interposer that includes through-silicon vias (TSVs). The TSVs provide vertical electrical connections that pass through the substrate 10 to establish electrical connections from one face to an opposite face. The TSVs may be fabricated by etching vias into the substrate 10, filling the resulting vias with a conductor, and a backside reveal process. A doped region (not shown) may be used to electrically isolate the doped band 38 and the deep trench capacitor 36 from the TSVs. For example, if the doped band 38 is comprised of n-type semiconductor material (e.g., silicon), the doped region may be comprised of p-type semiconductor material (e.g., silicon) formed by introducing (e.g., by ion implantation) a p-type dopant selected from Group III of the Periodic Table (e.g., boron (B)) that is effective to impart p-type conductivity to the semiconductor material.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. The chip may be integrated with other chips, discrete circuit elements, and/or other signal processing devices as part of either an intermediate product or an end product. The end product can be any product that includes integrated circuit chips, such as computer products having a central processor or smartphones.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refers to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature may be “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure comprising:
a first dielectric layer on a substrate, the first dielectric layer including a topmost surface and an opening that extends from the topmost surface through the first dielectric layer;
a deep trench capacitor including a deep trench in the substrate, a first plate, and a second plate located in the substrate proximate to a sidewall of the deep trench, the deep trench vertically aligned with the opening in the first dielectric layer, the first plate at least partially inside the deep trench and at least partially inside the opening in the first dielectric layer, and the first plate extending to the topmost surface of the first dielectric layer; and
a diffusion pad arranged at the topmost surface of the first dielectric layer relative to the opening such that the diffusion pad is coupled with the first plate of the deep trench capacitor, the diffusion pad comprised of doped polysilicon,
wherein the substrate is free of trench isolation regions adjacent to the first plate of the deep trench capacitor and the second plate of the deep trench capacitor, and the first dielectric layer electrically isolates the diffusion pad from the second plate of the deep trench capacitor.

2. The structure of claim 1 further comprising:
a band of doped semiconductor material located in the substrate beneath the first dielectric layer,
wherein the band of doped semiconductor material is coupled with the second plate.

3. The structure of claim 2 further comprising:
a source/drain region of a field-effect transistor,
wherein the second plate is coupled with the source/drain region by the band of doped semiconductor material.

4. The structure of claim 3 further comprising:
a second dielectric layer located on the first dielectric layer; and
a contact extending through the second dielectric layer to the diffusion pad.

5. The structure of claim 2 wherein the band of doped semiconductor material and the second plate are comprised of respective semiconductor materials having the same conductivity type.

6. The structure of claim 2 wherein the band of doped semiconductor material penetrates to a shallower depth in the substrate than the deep trench.

7. The structure of claim 1 wherein the first plate is comprised of a layer of a conductor located on a sidewall of the deep trench and the doped polysilicon is received in a space inside the deep trench that is interior of the layer of the conductor.

8. The structure of claim 7 wherein the conductor is titanium nitride.

9. The structure of claim 1 wherein the substrate is a bulk semiconductor wafer.

10. The structure of claim 1 wherein the diffusion pad extends on the topmost surface of the first dielectric layer laterally of the opening, and further comprising:
a second dielectric layer located on the first dielectric layer; and
a contact extending through the second dielectric layer to the diffusion pad.

11. (canceled)

12. A method comprising:
forming a first dielectric layer on a substrate;
patterning an opening that extends from a topmost surface of the first dielectric layer through the first dielectric layer;
etching the substrate to form a deep trench in the substrate by extending the opening in the first dielectric layer to a depth into the substrate;
forming a first plate of a deep trench capacitor that is located at least partially inside the deep trench and at least partially inside the opening in the first dielectric layer;
planarizing the first plate to the topmost surface of the first dielectric layer;
forming a second plate located in the substrate proximate to a sidewall of the deep trench;
forming a diffusion pad arranged at the topmost surface of the first dielectric layer relative to the opening such that the diffusion pad is coupled with the first plate of the deep trench capacitor,
wherein the diffusion pad is comprised of doped polysilicon, the substrate is free of trench isolation regions adjacent to the first plate of the deep trench capacitor and the second plate of the deep trench capacitor, and the first dielectric layer electrically isolates the diffusion pad from the second plate of the deep trench capacitor.

13. The method of claim 12 further comprising:
ion implanting the substrate adjacent to the sidewall of the deep trench to form the second plate.

14. The method of claim 13 further comprising:
forming a band of doped semiconductor material located in the substrate beneath the first dielectric layer,
wherein the band of doped semiconductor material is coupled with the second plate.

15. The method of claim 14 further comprising:
forming a source/drain region of a field-effect transistor that intersects the band of doped semiconductor material,
wherein the second plate is coupled with the source/drain region by the band of doped semiconductor material.

16. The method of claim 15 further comprising:
forming a second dielectric layer located on the first dielectric layer; and
forming a first contact extending through the second dielectric layer to the diffusion pad.

17. The method of claim 16 further comprising:
forming a second contact extending through the second dielectric layer to the source/drain region,
wherein the first contact and the second contact are concurrently formed.

18. The method of claim 12 wherein forming the first plate of the deep trench capacitor comprises:
forming a layer of a conductor on a sidewall of the deep trench; and
forming, with a single deposition, the doped polysilicon filling space inside the deep trench interior of the layer of the conductor.

19. The method of claim 12 further comprising:
forming a second dielectric layer located on the first dielectric layer; and
forming a contact extending through the second dielectric layer to the diffusion pad.

20. The method of claim 12 wherein forming the diffusion pad arranged at the topmost surface of the first dielectric layer comprises:
depositing a layer of the doped polysilicon on the topmost surface of the first dielectric layer; and
patterning the layer of the doped polysilicon to form the diffusion pad.

21. The method of claim 20 wherein the diffusion pad extends on the topmost surface of the first dielectric layer laterally of the opening.
